(19) United States
(12) Patent Application Publication
(10) Pub. No.: US 2008/0035992 A1
(43) Pub. Date: Feb. 14, 2008

(54) SEMICONDUCTOR DEVICE

(75) Inventors: Yusuke KAWAGUCHI, Miura-gun (JP); Yoshihiro Yamaguchi, Saitama-shi (JP); Syotaro Ono, Yokohama-shi (JP); Akio Nakagawa, Chigasaki-shi (JP); Miwako Akiyama, Tokyo (JP); Kazuya Nakayama, Sagamihara-shi (JP); Masakazu Yamaguchi, Kawasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 11/836,383

(22) Filed: Aug. 9, 2007

(30) Foreign Application Priority Data
Aug. 9, 2006 (JP) 2006-216782
Jun. 25, 2007 (JP) 2007-165879

(51) Int. Cl. H01L 29/78

(52) U.S. Cl. 257/331; 257/E29.262

(57) ABSTRACT

This semiconductor device comprises a drift layer of a first conductivity type formed on a drain layer of a first conductivity type, and a drain electrode electrically connected to the drain layer. A semiconductor base layer of a second conductivity type is formed in a surface of the drift layer, and a source region of a first conductivity type is further formed in the semiconductor base layer.

A source electrode is electrically connected to the source region and a semiconductor base layer. Plural gate electrodes are formed through a gate insulation film so that a semiconductor base layer may be sandwiched by the gate electrodes. The width of the semiconductor base layer sandwiched by the gate electrodes is 0.3 micrometers or less.

### CROSS REFERENCE TO RELATED APPLICATIONS

This application is based on and claims the benefit of priority from prior Japanese Patent Application No. 2006-216782, filed on Aug. 9, 2006, and prior Japanese Patent Application No. 2007-165879, filed on Jun. 25, 2007, the entire contents of which are incorporated herein by reference.

### BACKGROUND OF THE INVENTION

1. Field of the Invention

The present invention relates to a semiconductor device, and more particularly, to a semiconductor device including a MOSFET.

2. Description of the Related Art

Recently, use of a power MOSFET has greatly increased not only in a market for large-current, high-breakdown voltage switching power supply but also in a market for energy switching devices for mobile communication devices such as note type personal-computers. The power MOSFET is applied to a power management circuit or a safety circuit for a lithium ion battery in these fields. Thus, the power MOSFET is exceedingly desired to attain low voltage operation, which makes it possible to be directly driven by a battery voltage and a low ON-state resistance. The applicant has proposed a semiconductor device for lowering the product of an ON resistance Ron and a capacitance Cgd between a gate and a drain, for example in JP 2005-11965 A.

The ON-resistance mainly consists of a channel resistance in a channel region, and a drift resistance in a drift layer. In a power MOSFET with a high-breakdown voltage, a current flowing in a drift layer is also high. Accordingly, a drift resistance affects the ON resistance of the whole element greatly.

However, in a device with a low breakdown voltage of about 30 volts, an influence of the drift resistance to the ON resistance becomes small relatively, and channel resistance affects the ON resistance greatly.

### SUMMARY OF THE INVENTION

In an aspect the present invention provides a semiconductor device comprising: a drain layer of a first conductivity type; a drift layer of a first conductivity type formed on the drain layer; a drain electrode electrically connected to the drain layer; a semiconductor base layer of a second conductivity type formed in a surface of the drift layer; a source region of a first conductivity type formed in the semiconductor base layer; a source electrode electrically connected to the source region and the semiconductor base layer; and a plurality of gate electrodes formed via a gate insulation film to sandwich the semiconductor base layer, wherein a width of the semiconductor base layer sandwiched by the plurality of gate electrodes is 0.3 micrometers or less.

### BRIEF DESCRIPTION OF THE DRAWINGS

FIG. 1 is a plan view of a semiconductor device according to the first embodiment of the present invention.

FIG. 2 is an A-A′ sectional view of FIG. 1.

FIG. 3 shows a graph of a simulation representing a relation between width x [um] of a p-type base layer 13 and a channel resistance (relative value) of one of the p-type base layer 13.

FIG. 4 is a sectional view of the semiconductor device according to the second embodiment of the present invention.

FIG. 5 is a sectional view of the semiconductor device according to the third the embodiment of the present invention.

FIG. 6 is a sectional view of the semiconductor device according to the fourth the embodiment of the present invention.

FIG. 7 shows a manufacturing process of the semiconductor device according to the fourth embodiment.

FIG. 8 shows a manufacturing process of the semiconductor device according to the fourth embodiment.

FIG. 9 shows a manufacturing process of the semiconductor device according to the fourth embodiment.

FIG. 10 shows a manufacturing process of the semiconductor device according to the fourth embodiment.

FIG. 11 shows a manufacturing process of the semiconductor device according to the fourth embodiment.

FIG. 12 shows a manufacturing process of the semiconductor device according to the fourth embodiment.

FIG. 13 shows a manufacturing process of the semiconductor device according to the fourth embodiment.

FIG. 14 shows a manufacturing process of the semiconductor device according to the fourth embodiment.

FIG. 15 shows a manufacturing process of the semiconductor device according to the fourth embodiment.

FIG. 16 is a sectional view of the semiconductor device according to the fifth the embodiment of the present invention.

FIG. 17 is a sectional view of the semiconductor device according to the sixth the embodiment of the present invention.

FIG. 18 is a sectional view of the semiconductor device according to a modification of the embodiments of the present invention.

FIG. 19 is a sectional view of the semiconductor device according to a modification of the embodiments of the present invention.

FIG. 20 is a sectional view of the semiconductor device according to a modification of the embodiments of the present invention.

FIG. 21 is a sectional view of the semiconductor device according to a modification of the embodiments of the present invention.

FIG. 22 is a sectional view of the semiconductor device according to a modification of the embodiments of the present invention.

FIG. 23 is a sectional view of the semiconductor device according to a modification of the embodiments of the present invention.

FIG. 24 shows a graph representing a property of the modification shown in FIG. 23.

### DETAILED DESCRIPTION OF THE EMBODIMENTS

Next, a semiconductor device according to an embodiment of the present invention is explained in detail with reference to drawings.

Although the first conductivity type is defined as an n-type and the second conductivity type is defined as a p-type in the explanation below, it is also possible that the first conductivity type is defined as a p-type and the second conductivity type is defined as an n-type.

In the explanation below, “n+ type” means that its impurity concentration is higher than “n type”. Also, “n type” means that its impurity concentration is higher than “n− type.” Similarly, “p+ type” means that its impurity concentration is higher than “p type”, and “p type” means that its impurity concentration is higher than “p− type.”

### First Embodiment

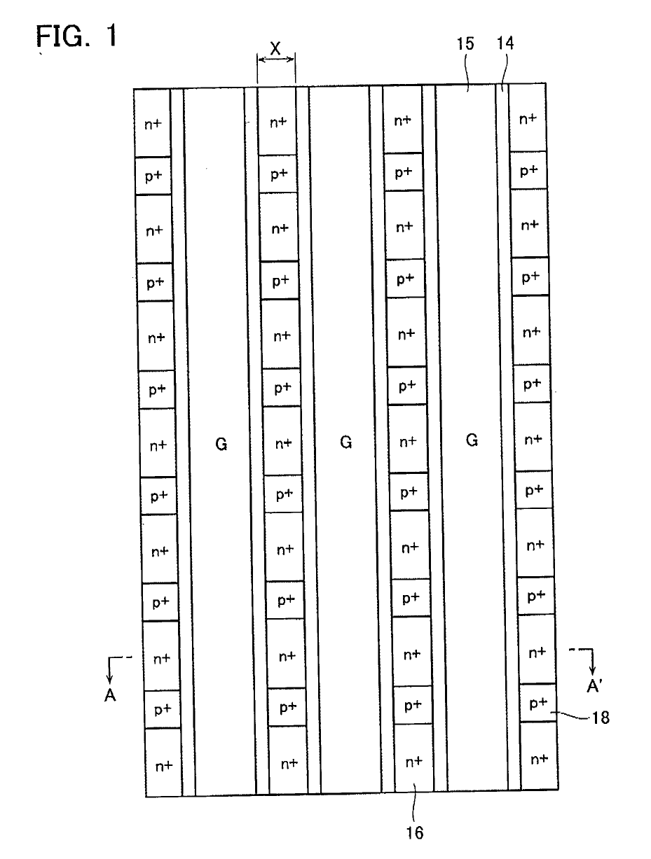

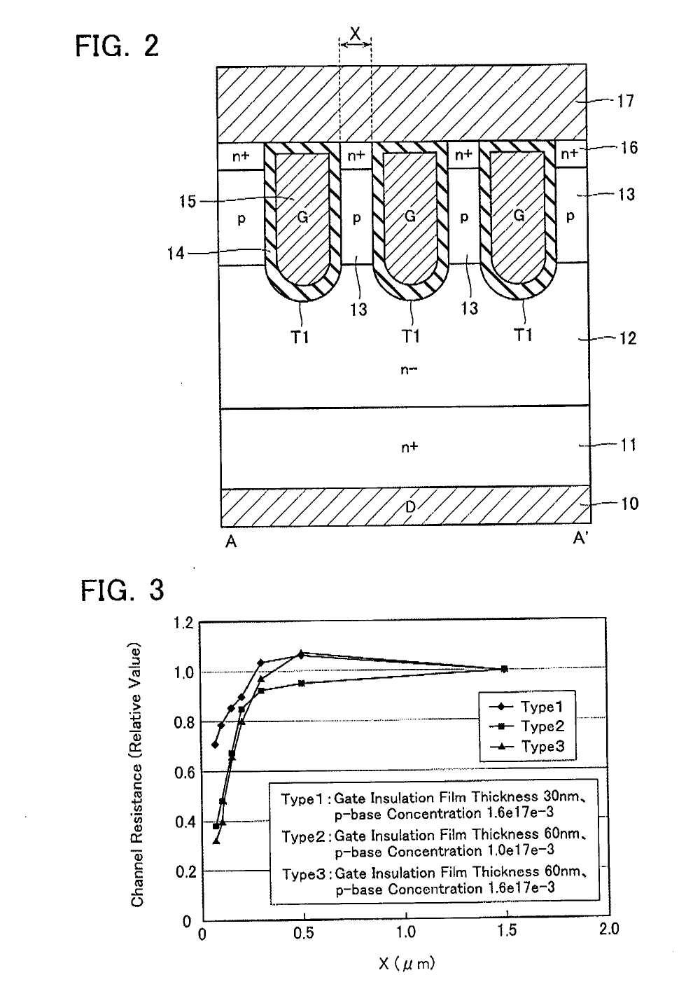

FIG. 1 is a plan view of a semiconductor device according to the first embodiment of the present invention, and FIG. 2 is the A-A′ sectional view of FIG. 1. As shown in FIG. 2, the semiconductor device according to this embodiment comprises an n+ type semiconductor substrate 11 as a drain region, and an n− type epitaxial layer 12 (a drift layer) formed thereon by epitaxial growth. The semiconductor device comprises a trench-gate-type MOSFET on this epitaxial layer 12. A drain electrode 10 is formed on a rear surface of the n+ type semiconductor substrate 11.

Furthermore, a p type base layer 13 is formed on the upper surface of the epitaxial layer 12 by epitaxial growth. Plural trenches T1 are formed in this p type base layer 13 at equal intervals by photolithography and reactive ion etching (RIE). The trenches T1 are formed so that a width x of the p type base layer 13 sandwiched therebetween is set at 0.3 micrometers or less.

In the trenches T1, the gate electrode 15 formed of polysilicon or the like is embedded through a gate insulation film 14. Moreover, an n+ type source region 16 is formed on the surface of the p type base layer 13 sandwiched between the gate electrodes 15. The source region 16 is electrically connected to a source electrode 17.

In addition, as shown in FIG. 1, the gate electrode 15 is formed in a shape of a stripe prolonged in a direction perpendicular to the paper in FIG. 2. Moreover, the source region 16 and the p+ type contact layer 18 are formed in turn on the surface of the p type base layer 13 aligned along the longitudinal direction of the gate electrode 15.

The contact layer 18 is electrically connected to the source electrode 17 with the source region 16. Note that the contact layer 18 is preferably formed to have a depth of 50% or more of the depth of the trench T1.

As described above, it is preferable that the width x of the p type base layer 13 sandwiched by the plural gate electrodes 15 is 0.3 micrometers or less.

When the width of the p type base layer 13 is set at that range, the following effects will arise. That is, when a certain gate voltage is applied to the gate electrode 14 and the MOSFET is in a conductive state, an inversion layer (a channel) is formed in the p type base layer 13 along the gate insulation film 14, and the other region thereof is wholly depleted. For this reason, the whole of the p type base layer 13 substantially functions as a channel and the degree of channel mobility increases. In other words, a channel resistance can be reduced.

FIG. 3 shows a graph of a simulation representing a relation between width x [um] of the p-type base layer 13 and a channel resistance (relative value) of one of the p-type base layer 13 divided by the trenches Ti.

As apparent from FIG. 3, when x is larger than 0.3 [um], a channel resistance of each of the p type base layer 13 is almost constant. When x is 0.3 [um] or less, each channel resistance of the p type base layer 13 will fall gradually. This phenomenon can be observed even if a thickness of the gate insulation film 14 varies, or impurity concentration of the p type base layer 13 varies (see Type 1-3 in FIG. 3). The reason why a channel resistance of each of the p type base layer 13 is almost constant when x is larger than 0.3 [um] is thought as follows. That is, in a conductive state of the MOSFET, a region except the inversion layer in the p type base layer 13 does not fully depleted, and this region remains as a neutral region where careers are still alive. This may prevent channel mobility from being increased.

The neutral region disappears and whole of the p type base layer 13 is depleted except for the inversion layer, when x is 0.3 [um] or less. Therefore, channel mobility increases, and a channel resistance decreases.

### Second Embodiment

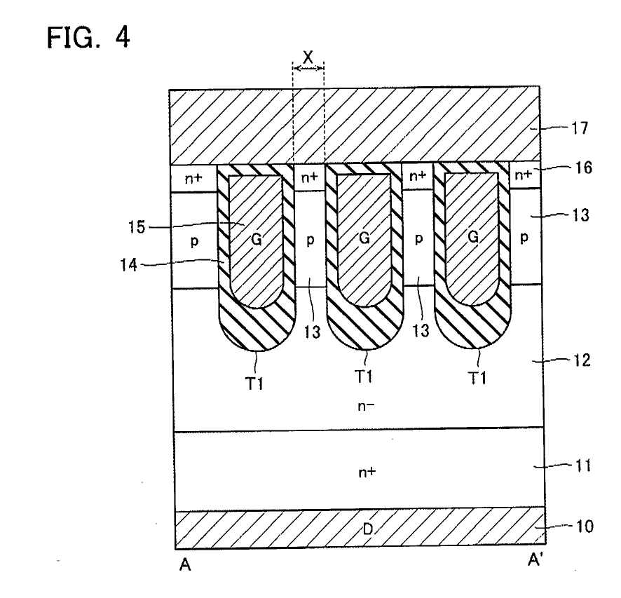

Next, with reference to FIG. 4, a sectional view of the semiconductor device according to the second embodiment of the present invention is explained. A plan view is as shown in FIG. 1 of the first embodiment, and FIG. 4 shows the A-A′ sectional view thereof. Moreover, in FIG. 4, since the same reference numerals are given to the same components as those in the first embodiment, the detailed explanation thereof is omitted hereinbelow.

In the second embodiment, a thickness of the gate insulation film 14 is enlarged near the bottom of the trench T1 rather than its side portion. Thereby, the gate-drain capacitance Cgd can be reduced and the switching speed of the MOSFET can be accelerated.

Also in this embodiment, it is preferable that the width x of the p type base layer 13 sandwiched by the plural gate electrodes 15 is 0.3 micrometers or less.

When the width of the p type base layer 13 is set at that range, with a certain gate voltage applied to the gate electrode 14 to make the MOSFET conductive, an inversion layer (a channel) is formed in the p type base layer 13 along the gate insulation film 14, and the other region thereof is wholly depleted. For this reason, the whole of the p type base layer 13 substantially functions as a channel. Therefore, channel mobility increases, and the channel resistance decreases.

### Third Embodiment

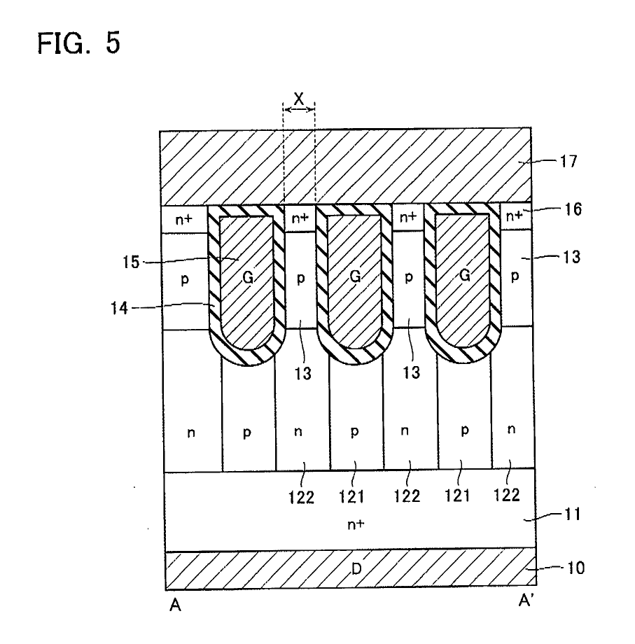

Next, with reference to FIG. 5, a sectional view of the semiconductor device according to the third embodiment of the present invention is explained. The plan view of this semiconductor device is as shown in FIG. 1 of the first embodiment, and FIG. 5 shows a A-A′ sectional view.

In FIG. 5, since the same reference numerals are given to the same components as the embodiments described above, the detailed explanation thereof is omitted hereinbelow.

The semiconductor device according to the third embodiment differs from the above-described embodiments in that it forms a drift layer called “superjunction” structure on the n− type epitaxial layer 12. A superjunction structure is made by forming a p type pillar layer 121 and an n type pillar layer 122 in the lateral direction in turn.

When the MOSFET is in a conductive state, the n type pillar layer 122 in the superjunction structure functions as a drift layer. On the other hand, when the MOSFET is in a non-conductive state, the superjunction structure is quickly depleted by a reverse bias between the p type pillar layer 121 and the n type pillar layer 122. Thereby it becomes possible to attain a low ON-resistance and a high breakdown voltage property at the same time, and to reduce a gate-drain capacitance Cgd.

Also in this embodiment, it is preferable that the width x of the p type base layer 13 sandwiched between the plural gate electrodes 15 is 0.3 micrometers or less. When the width of the p type base layer 13 is set at that range, with a certain gate voltage applied to the gate electrode 14 to make the MOSFET conductive, an inversion layer (a channel) is formed in the p type base layer 13 along the gate insulation film 14, and the other region is wholly depleted. For this reason, the whole of the p type base layer 13 substantially functions as a channel. Therefore, channel mobility increases, and a channel resistance decreases.

### Fourth Embodiment

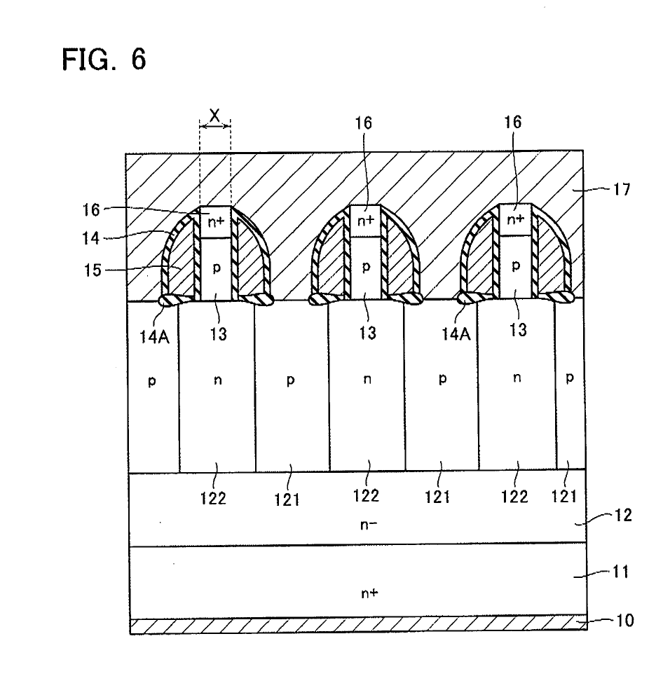

Next, with reference to FIG. 6, a semiconductor device according to the fourth embodiment of the present invention is explained. In FIG. 6, the same reference numerals are given to the same components as the above-described embodiments, and the detailed explanation thereof is omitted hereinbelow.

The semiconductor device of this embodiment is common with the third embodiment in that it forms a drift layer having a so-called superjunction structure in which a p type pillar layer 121 and an n type pillar layer 122 are formed in the lateral direction in turn on the n− type epitaxial layer 12.

However, the device according to this embodiment differs from the above-described embodiments in that the p type base layer 13 is formed on the upper side of the n type pillar layer 122, and the gate electrodes 15 are formed on both sides (right and left) of the p type base layer 13, by deposition using a CVD method or the like and reactive ion etching (RIE), without forming trenches. Accordingly, this gate electrode 15 has an approximately triangle-like form whose bottom length is larger than its upper length.

The gate electrode 15 is insulated or isolated from the source electrode 17, like the above-described embodiments. In addition, the bottom 14A of the gate insulation film 14′ is larger in film thickness by LOCOS (Local Oxidation of Silicon) compared to its side. Thereby, the gate-drain capacitance Cgd may be reduced and the switching speed of the MOSFET can be accelerated.

Also in this embodiment, it is preferable that the width x of the p type base layer 13 sandwiched between the plural gate electrodes 15 is 0.3 micrometers or less. When the width of the p type base layer 13 is set at that range, with a certain gate voltage applied to the gate electrode 14 to make the MOSFET conductive, an inversion layer (a channel) is formed in the p type base layer 13 along the gate insulation film 14, and the other region is wholly depleted. For this reason, the whole of the p type base layer 13 substantially functions as a channel. Therefore, channel mobility increases, and a channel resistance decreases.

Moreover, an n+ type source region 16 is formed on the surface of the p type base layer 13 sandwiched between the gate electrodes 15. The source electrode 17 is electrically connected to this source region 16. Although not illustrated in the figure, the source electrode 17 is electrically connected also to the base layer 13 like the first embodiment by the p type contact layer 18 (FIG. 1) formed aligned with the source region 16 in the direction perpendicular to the paper.

Also in this embodiment, the width x of the p type base layer 13 may be 0.3 micrometers or less. This makes the p base layer 13 to be inverted when a certain gate voltage is applied to the gate electrode 14 to make the MOSFET conductive, thereby the region other than the inversion layer being depleted. Therefore, channel mobility increases and a channel resistance decreases, thereby an ON-resistance of the MOSFET being lowered.

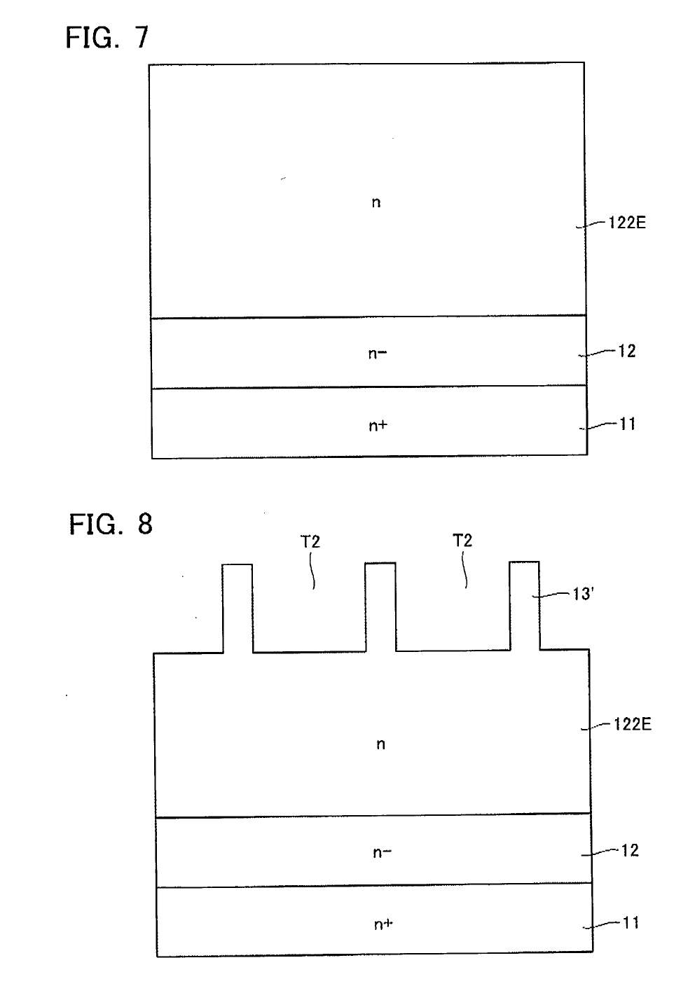

The manufacturing process of the semiconductor device according to the fourth embodiment is explained with reference to FIGS. 7 to 16. First, as shown in FIG. 7, an n− type epitaxial layer 12 is formed on the n+ type semiconductor substrate 11 by epitaxial growth. Subsequently, an n type epitaxial layer 122E is epitaxially grown to form n type pillar layers 122 in the superjunction structure.

Then, by photolithography and etching, as shown in FIG. 8, trenches T2 are formed on the surface of the epitaxial layer 122E so that it may leave pillar layers 13′ used later as the p type base layers 13.

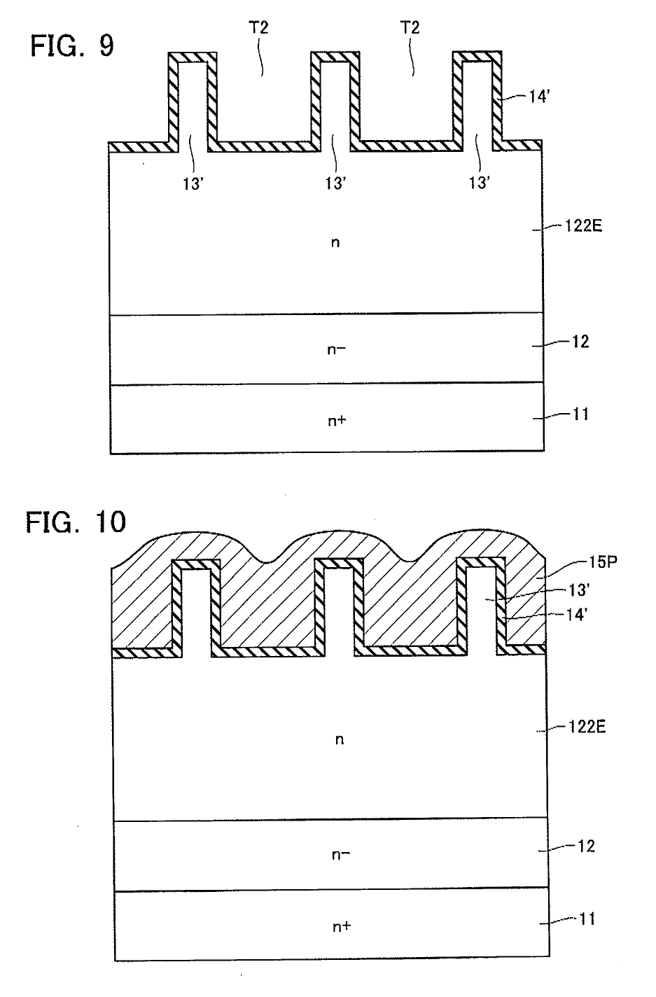

And as shown in FIG. 9, a silicon oxide film 14′ to form a gate insulation film 14 is formed by thermal oxidation on the entire surface of the epitaxial layer 122E, including the inner wall of the trenches T2. Then, as shown in FIG. 10, the polysilicon film 15P used as the gate electrode 15 is deposited by a CVD method on the entire surface of the silicon oxide film 14′.

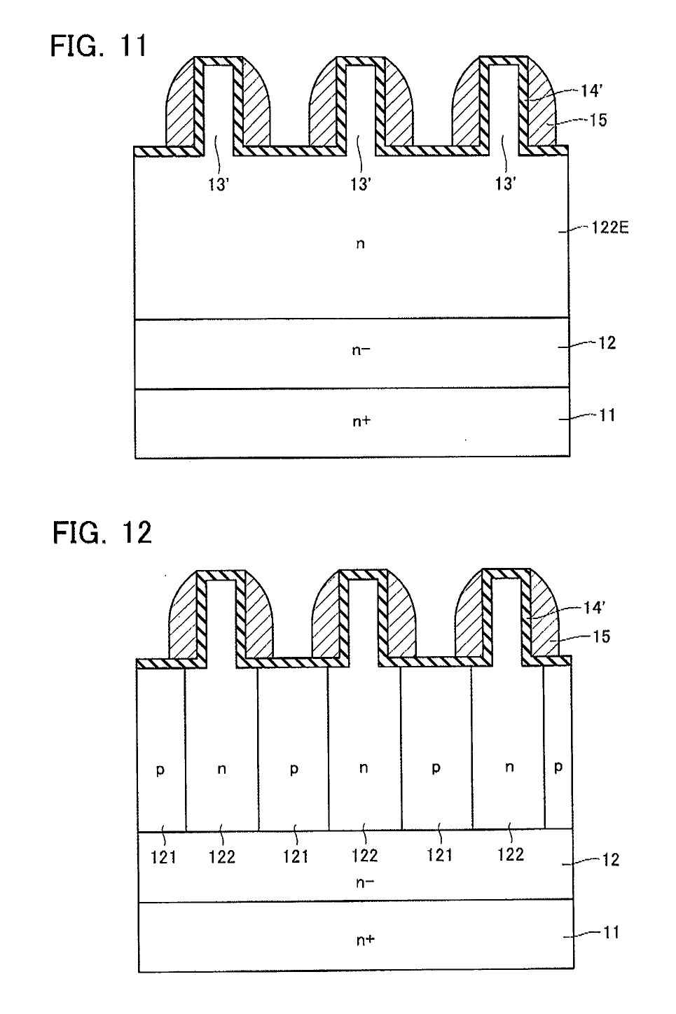

Then, as shown in FIG. 11, this polysilicon film 15P is etched by RIE, thereby the gate electrode 15 being formed.

Thereafter, fast-ion implantation of boron (B) as p type impurity using the gate electrode 15 as a mask, and thermal diffusion thereof are carried out. Thereby, as shown in FIG. 12, the super junction structure is formed in which the p type pillar layer 121 and the n type pillar layer 122 are formed in turn.

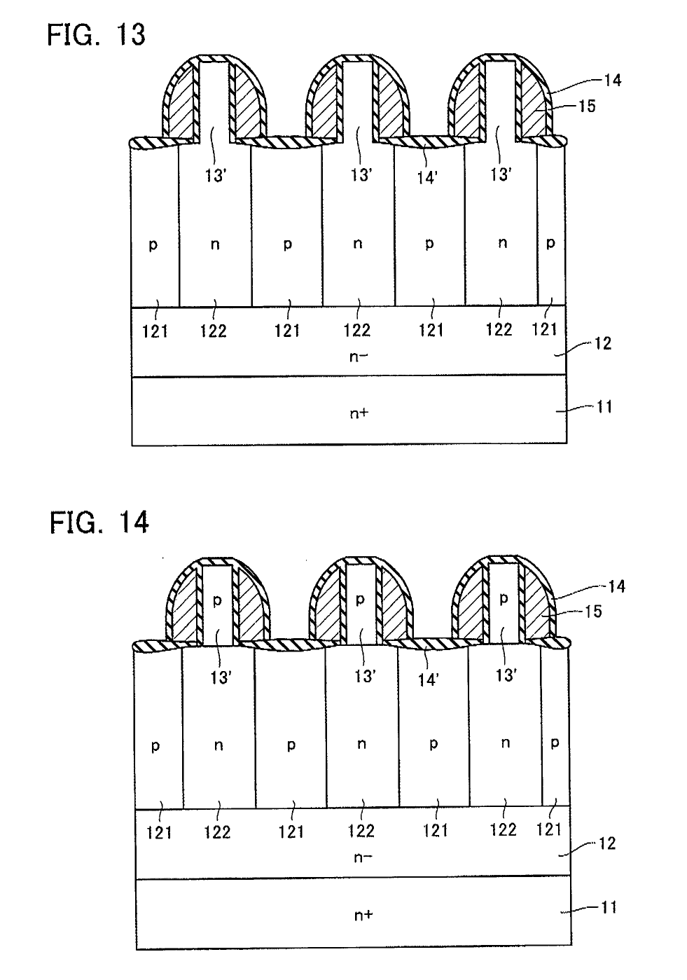

Next, as shown in FIG. 13, a silicon oxide film to form the gate insulation film 14 is formed also on the outer side surface of the gate electrode 15. Moreover, LOCOS oxidization at the bottom of the gate insulation film 141 is carried out to enlarge the film thickness.

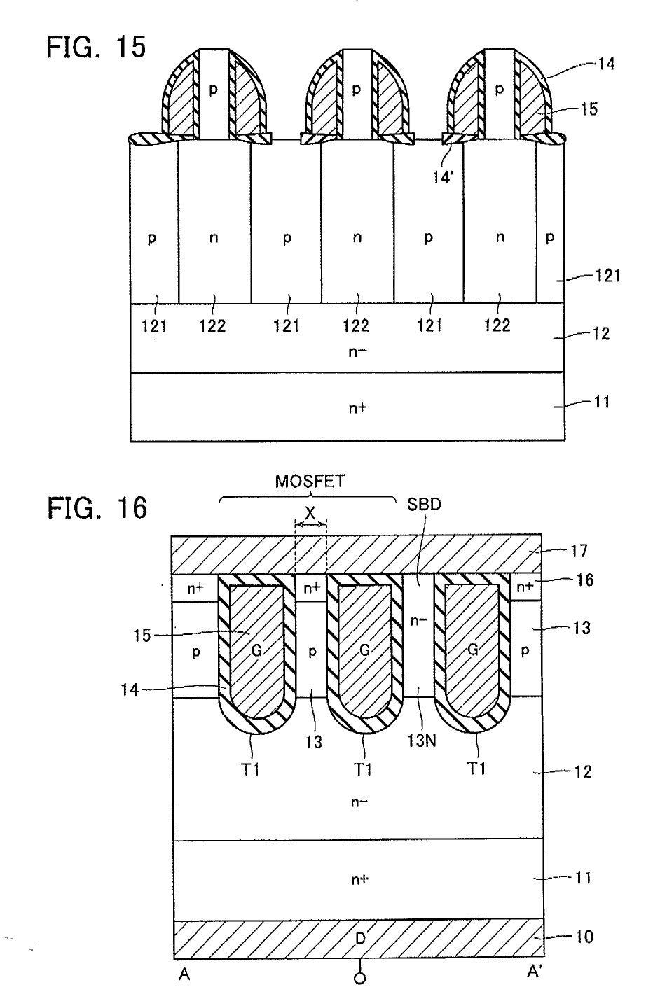

Subsequently, as shown in FIG. 14, selective ion implantation of boron (B) is conducted in the pillar layer 13′. Thereby, the pillar layer 13′ is transformed into p-type, that is, into the p type base layer 13. Furthermore, as shown in FIG. 15, etching of the gate insulation film 14 is performed to remove the insulation film existing on the p type pillar layer 121 and the p type base layer 13.

Then, the semiconductor device shown in FIG. 6 is completed by performing ion implantation to the p type base layer 13 to form the n+ type source layer 16 and the p+ type contact layer 18 on the surface of the p type base layer 13 in turn in a direction perpendicular to the paper, and by forming the electrodes 10 and 17.

### Fifth Embodiment

Next, with reference to FIG. 16, the semiconductor device according to the fifth embodiment of the present invention is explained. The structure of this embodiment in view of a fundamental structure is the same as the first embodiment. Moreover, in FIG. 16, since the same reference numerals are given to the same components as those in the first embodiment, the detailed explanation thereof is omitted hereinbelow.

This semiconductor device differs from the above-described embodiments in that Schottky barrier diodes SBD are formed on the same substrate as the MOSFETs. That is, ion implantation of n type impurity, such as phosphorus(P) is conducted in at least part of the p type base layer 13 formed between the plural gate electrodes 15. Thereby, a region 13N is transformed into an n type. This region 13N functions as a Schottky barrier diode SBD.

Forming Schottky barrier diodes SBD in part among the plural MOSFETs makes a switching speed of a semiconductor device higher, and makes electric power loss to be lessened.

As compared to the diode with a normal PN junction, a Schottky barrier diode has a lower barrier height and a lower forward direction voltage. Moreover, since conduction of a career is performed by the electron as a majority carrier, a reverse recovery time is short and a switching speed is also small. For this reason, improvement in a switching speed and a reduction of an electric power loss can be obtained by forming Schottky barrier diodes SBD in a part of the base layer 13. Note that the gate electrode 15 adjacent to the n type region 13N in which Schottky barrier diode SBD is formed is short-circuited to the source electrode 17 in a region not illustrated to have the same potential.

In addition, in FIG. 16, although the drift layer has been explained as a single n type epitaxial layer 12, it is needless to say that a so-called superjunction structure as shown in FIG. 5 and the like may be employed for the drift layer.

Also in this embodiment, it is preferable that the width x of the p type base layer 13 sandwiched between the plural gate electrodes 15 is 0.3 micrometers or less. When the width of the p type base layer 13 is set at that range, with a certain gate voltage applied to the gate electrode 14 to make the MOSFET conductive, an inversion layer (a channel) is formed in the p type base layer 13 along the gate insulation film 14, and the other region is wholly depleted. For this reason, the whole of the p type base layer 13 substantially functions as a channel. Therefore, channel mobility increases, and the channel resistance decreases.

### Sixth Embodiment

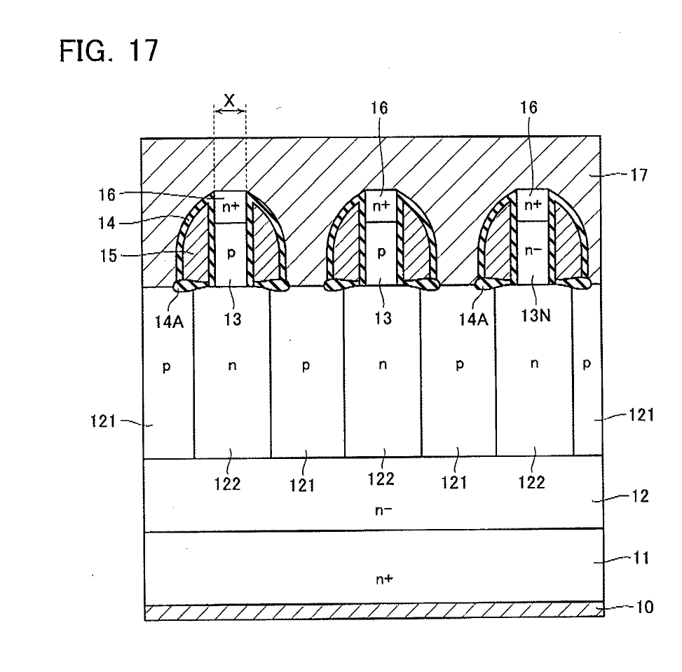

Next, with reference to FIG. 17, a semiconductor device according to the sixth embodiment of the present invention is explained. The structure of this embodiment in view of a fundamental structure is the same as the first embodiment. Moreover, in FIG. 16, since the same reference numerals are given to the same components as those in the first embodiment, the detailed explanation thereof is omitted hereinbelow.

This semiconductor device forms MOSFETs and Schottky barrier diodes SBD on the same substrate like the fifth embodiment. That is, ion implantation of n type impurity, such as phosphorus(P) is conducted in at least part of the p type base layer 13 formed between the plural gate electrodes 15. Thereby, a region 13N is transformed into an n type. A Schottky barrier diode SBD is formed in this region 13N. Forming Schottky barrier diodes SBD in part of the base layer 13 makes a switching speed of a semiconductor device higher, and makes electric power loss to be lessened. Note that the gate electrode 15 adjacent to the n type region 13N in which Schottky barrier diode SBD is formed is short-circuited to the source electrode 17 in a region not illustrated to have the same potential.

Also in this embodiment, it is preferable that the width X of the p type base layer 13 sandwiched between the plural gate electrodes 15 is 0.3 micrometers or less.

### Others

Although the embodiments of invention has been explained above, the present invention is not limited to this. Various changes, additions and the like are possible without departing from the spirit of the present invention.

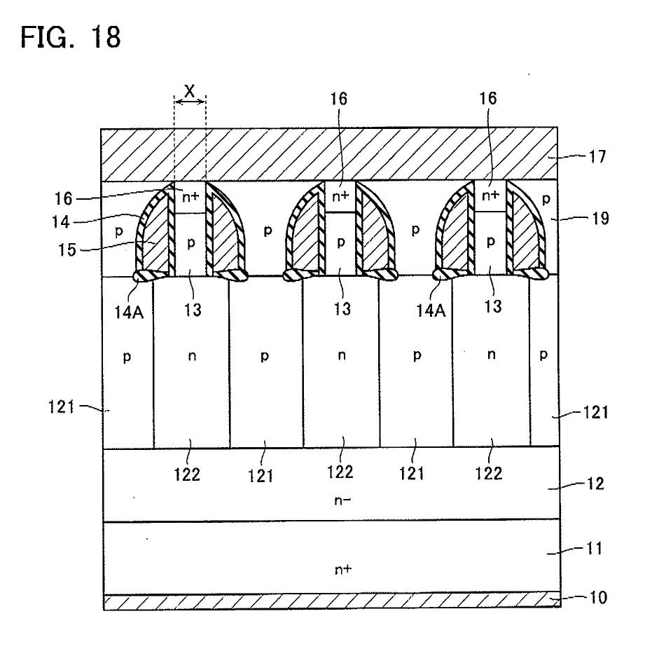

For example, in the fourth or the sixth embodiment, the p type pillar layer 171 and the source electrode 17 is directly connected by the source electrode 17. Instead, as shown in FIG. 18, it is also possible to form a p type layer 19 separately between the gate electrodes 15. The p type pillar layer 121 and the source electrode 17 may be connected through this p type layer 19.

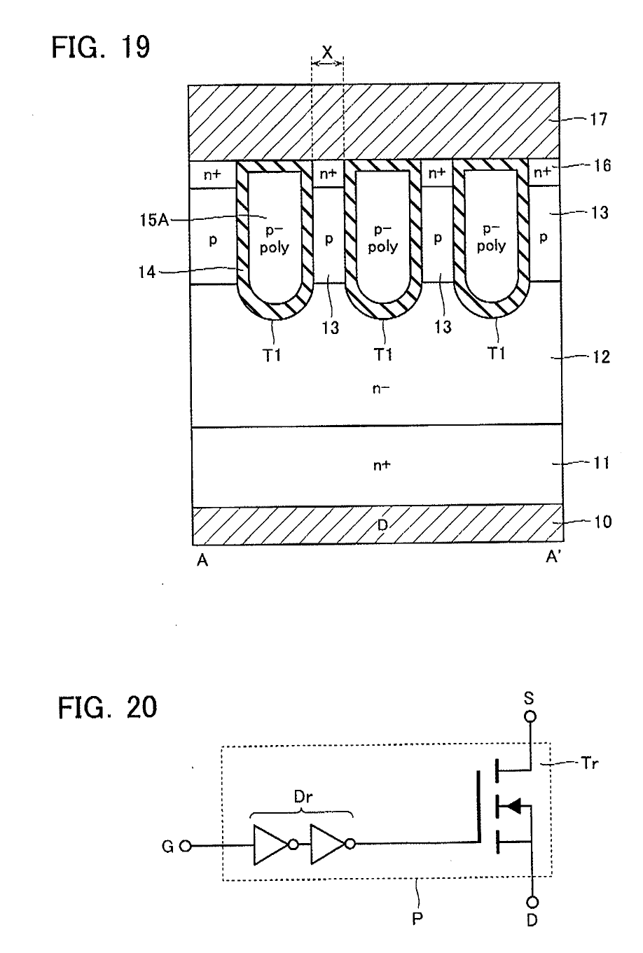

Moreover, as shown in FIG. 19, p type polysilicon may be used as a material of the gate electrode 15. In this case, a channel resistance can be reduced compared to the case where the gate electrode 15 is formed of n type polysilicon. That is, when the gate electrode 15 is formed of n-type polysilicon, the impurity concentration of the p type base layer 13 must be 2.8e17 cm-3 in order to obtain 3V as a threshold voltage of the MOSFET,

On the other hand, when p type polysilicon is used as a material for the gate electrode 15, the impurity concentration of the p type base layer 13 required to obtain the threshold voltage of 3V is 1.8e17 cm-3. Accordingly, a channel resistance can be reduced by 30% or more.

Moreover, in the above-described embodiments, when the width x of the semiconductor base layer 13 is reduced to 0.3 micrometers or less, the threshold voltage may become small. In this case, it becomes difficult to drive it with a conventional external drive circuit.

In this case, as shown in FIG. 20, it is preferable to form a gate drive circuit Dr for driving the semiconductor device Tr of the embodiments in the same package P. Thereby, the optimal drive can be obtained even if a threshold voltage thereof falls.

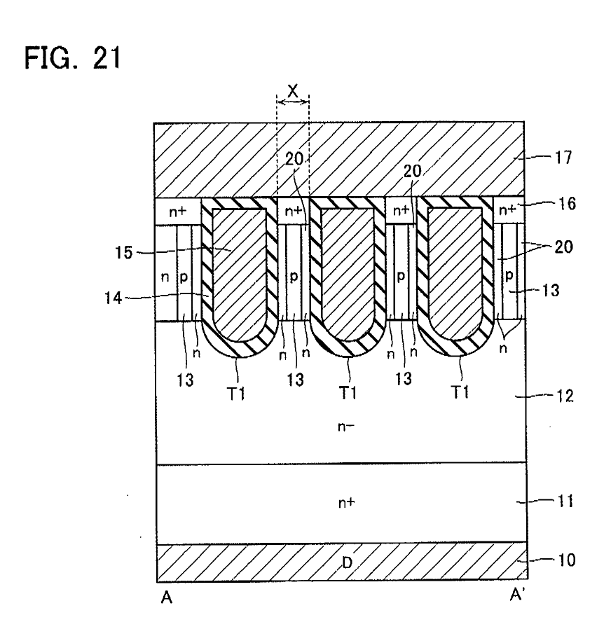

Moreover, for example, as shown in FIG. 21, an n-type layer 20 can also be formed along the side of the p type base layer 13 (namely, interface with the gate insulation films 14). In this case, since the threshold voltage of the MOSFET can be controlled by changing suitably impurity concentration of the p type base layer 13, and impurity concentration of the n-type layer 20, it becomes possible to reduce a channel resistance, keeping a threshold voltage constant. Such an n-type layer 20 can be formed by slanting-ion-implantation of phosphorus as n-type impurity, when the trench T1 in which the gate electrode 15 is formed is etched.

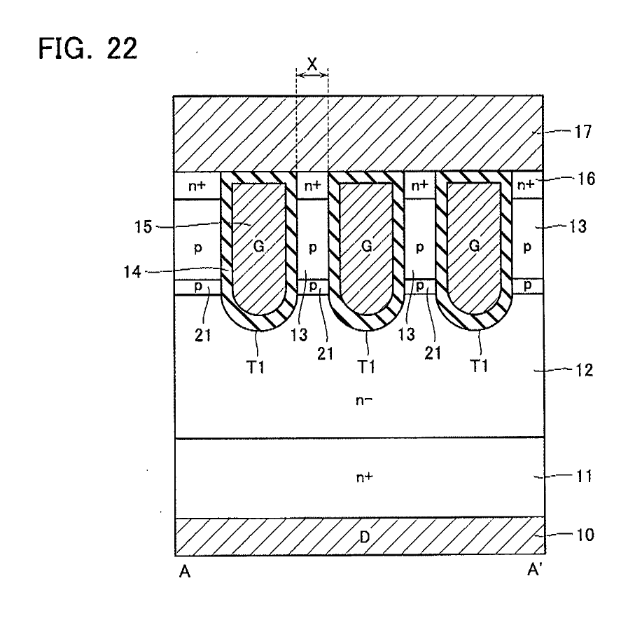

Moreover, as shown in FIG. 22, a p type layer 21 whose impurity concentration is higher than the p type base layer 13 can also be formed at the bottom of the p type base layer 13, i.e., a junction with the n− type epitaxial layer 12. Also in this case, the threshold voltage can be adjusted by controlling impurity concentration of the p type layer 21. Therefore, the impurity concentration of the p type base layer 13 may be sustained at a low value, and therefore the channel resistance may be reduced. In addition, in FIG. 22, it is also possible to form an n-type layer 20 as shown in FIG. 21 with the p type layer 21.

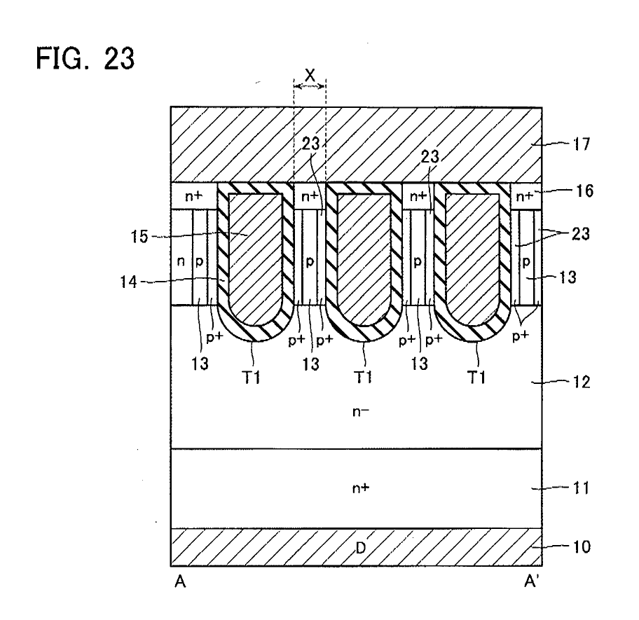

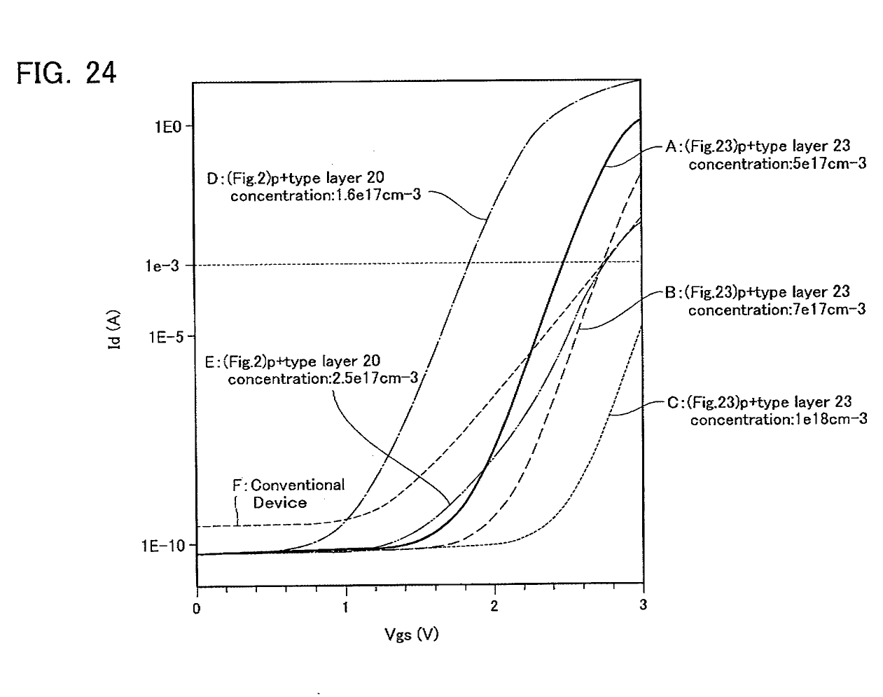

Moreover, for example, as shown in FIG. 23, a p+ type layer 23 can also be formed at the side of the p type base layer 13 (namely, interface with the gate insulation films 14). In this case, the threshold voltage of the MOSFET is controllable like in the case of FIG. 21 by changing suitably impurity concentration of the p type base layer 13, and impurity concentration of the p+ type layer 23. Such a p+ type layer 23 can be formed by slanting ion implantation of boron as p type impurity when the trench T1 in which the gate electrode 15 is formed is etched.

FIG. 24 shows a graph (simulation result) showing the relation between the gate-source voltage Vgs and drain current Id when impurity concentration of the p+ type layer 23 is changed at several intervals in the case of FIG. 23.

In FIG. 24, a curve A shows a case where impurity concentration of the p type base layer 13 is set at 1.6e17 cm-3 and impurity concentration of the p+ type layer 23 is set at 5e17 cm-3. A curve B shows a case where impurity concentration of the p type base layer 13 is set at 1.6e17 cm-3 and impurity concentration of the p+ type layer 23 is set at 7e17 cm-3. A curve C shows a case where impurity concentration of the p type base layer 13 is set at 1.6e17 cm-3 and impurity concentration of the p+ type layer 23 is set at 1e18 cm-3.

For comparison, a curb D shows a case where impurity concentration of the whole p+ type base layer 13 is set at 1e18 cm-3 in the first embodiment (FIG. 2). A curb E shows a case where impurity concentration of the whole p+ type base layer 13 is set at 2.5e18 cm-3 in the first embodiment (FIG. 2). A curb F shows a case where the p type base layer 13 has a long lateral width in the conventional device.

As shown in the curves D and E, if the impurity concentration of the whole p type base layer 13 becomes high, a threshold voltage can be high. But at the same time a gain Gm (a gradient in the graph) also becomes small. On the other hand, as shown by the curve A, B, and C, changing the impurity concentration of the p+ type layer 23 enables the threshold voltage only, while hardly changing the gain Gm.

What is claimed is:

1. A semiconductor device comprising:
a drain layer of a first conductivity type;
a drift layer of a first conductivity type formed on the drain layer;
a drain electrode electrically connected to the drain layer:
a semiconductor base layer of a second conductivity type formed in a surface of the drift layer;
a source region of a first conductivity type formed in the semiconductor base layer:
a source electrode electrically connected to the source region and the semiconductor base layer; and
a plurality of gate electrodes formed via a gate insulation film to sandwich the semiconductor base layer,
wherein a width of the semiconductor base layer sandwiched by the plurality of gate electrodes is 0.3 micrometers or less.

2. The semiconductor device according to claim 1, wherein the plurality of gate electrodes are embedded in trenches formed in the semiconductor base layer.

3. The semiconductor device according to claim 2, wherein the gate insulation film has a larger thickness at the bottom of the trench than at a side surface, thereof

4. The semiconductor device according to claim 1, wherein the drift layer is formed by arranging in turn a pillar layer of a first conductivity type and a pillar layer of a second conductivity type in a lateral direction.

5. The semiconductor device according to claim 1, wherein the gate electrode is formed beside the semiconductor base layer to have a larger length at its bottom than at its top, and
the gate insulation film is formed to have a larger thickness at its bottom than at its side.

6. The semiconductor device according to claim 4, wherein the pillar layer and the gate electrode are formed in a form of stripe with a first direction as a longitudinal direction.

7. The semiconductor device according to claim 6, wherein the source region and a contact layer of a second conductivity type are formed in a surface of the pillar layer in turn along the first direction.

8. The semiconductor device according to claim 1, wherein at least a part of the semiconductor base layer sandwiched between the plurality of gate electrodes is transformed to a first conductivity type.

9. The semiconductor device according to claim 8, wherein the semiconductor base layer of the first conductivity type functions as a Schottky barrier diode, and the semiconductor base layer of the second conductivity type serves as a MOSFET.

10. The semiconductor device according to claim 1, wherein the gate electrode is formed of polysilicon of a second conductivity type.

11. The semiconductor device according to claim 1, further comprising a semiconductor layer of a first conductivity type formed between the semiconductor base layer and the gate insulation film.

12. The semiconductor device according to claim 1, further comprising a semiconductor layer of a second conductivity type formed in the bottom of the semiconductor base layer, and having impurity concentration higher than that of the semiconductor base layer.

13. The semiconductor device according to claim 1, further comprising a gate drive circuit connected to the gate electrode, wherein the gate drive circuit is formed in the same package as a semiconductor element with the gate electrode.

14. The semiconductor device according to claim 1, further comprising a semiconductor layer of a second conductivity type formed between the semiconductor base layer and the gate insulation film, and having impurity concentration higher than the semiconductor base layer.
